(19) United States
(12) Patent Application Publication
(10) Pub. No.: US 2022/0359777 A1
(43) Pub. Date: Nov. 10, 2022

(54) ASSEMBLY FOR COVERING A SURFACE

(71) Applicant: TOTAL RENEWABLES, Courbevoie (FR)

(72) Inventor: Valérick CASSAGNE, Limours (FR)

(21) Appl. No.: 17/788,988

(22) PCT Filed: Dec. 18, 2020
(86) PCT No.: PCT/EP2020/086999

§ 371 Date: Jun. 24, 2022

(30) Foreign Application Priority Data
Dec. 24, 2019 (FR) 1915571

(51) Int. Cl. H01L 31/048; H02S 20/23

(52) U.S. Cl. CPC H01L 31/0488; H02S 20/23

(57) ABSTRACT

The present invention relates to an assembly (I) for covering a surface, in particular a roof, comprising:—a support membrane (13),—a laminate (2) comprising:—at least one layer of photovoltaic cells (3) connected to each other,—a front encapsulation layer (5) and a rear encapsulation layer (7) sandwiching the layer of photovoltaic cells (3), in which at least one of the encapsulation layers (5, 7) comprises glass fibers (9) and in which the assembly comprising the support membrane (13) bonded to the laminate (2) has a stiffness and an inertia such that the product of the stiffness and the inertia is greater than 30,000 daN·kg·m³.

The present invention relates to the field of surface coverings and, in particular, roof coverings and, in particular, surface coverings comprising photovoltaic modules.

More and more photovoltaic modules are placed on the roofs of buildings or urban structures, even on vehicles or light structures, to convert solar energy into electrical energy.

In order to facilitate their installation and limit their weight, it is also known to use flexible photovoltaic modules without glazed surfaces and metal structure, their low weight allowing their easy installation.

However, in the event of severe weather and in particular hail, such flexible photovoltaic modules tend to deform strongly under the impact of hailstones, which can damage the photovoltaic cells and cause a malfunction of the photovoltaic module when the local deformation of the module is greater than an admissible curvature limit threshold.

In order to at least partially overcome these technical problems, it is necessary to provide a solution allowing the installation of photovoltaic surface coverings comprising photovoltaic modules with reduced weight and resistant to hailstones producing a kinetic energy of up to 2.2 joules on impact according to the IEC 61215-2 standard.

To this end, the present invention relates to an assembly for surface covering, in particular a roof, comprising:

a support membrane,

a laminate comprising:

at least one layer of photovoltaic cells connected together,

a front encapsulation layer and a rear encapsulation layer sandwiching the layer of photovoltaic cells,

in which at least one of the encapsulation layers comprises glass fibers and in which the assembly comprising the support membrane bonded to the laminate has a stiffness and an inertia such that the product of the stiffness and the inertia is greater than 30,000 daN·kg·m⁻³

According to one aspect of the present invention, the assembly comprising the support membrane bonded to the laminate has a stiffness greater than 10 daN/mm.

According to one aspect of the present invention, the assembly comprising the support membrane bonded to the laminate has an inertia of at least 5 kg/m².

According to one embodiment of the present invention, the bonding surface represents at least 90% of an intermediate zone located between the support membrane and the laminate.

According to one aspect of the present invention, the length of the minor dimension of a portion of the intermediate zone without adhesive is less than 10 mm and its thickness is less than 1 mm.

According to another aspect of the present invention, the adhesive thickness is between 200 μm and 1.5 mm.

According to one embodiment of the present invention, the support membrane is a bituminous membrane.

According to another embodiment of the present invention, the glass fibers are arranged in the front encapsulation layer.

According to another embodiment of the present invention, the glass fibers are arranged in the rear encapsulation layer.

According to one embodiment of the present invention, the glass fibers are arranged in the front encapsulation layer and in the rear encapsulation layer.

According to one embodiment of the present invention, the front and rear encapsulation layers have a thickness of between 0.5 and 3 mm.

According to one embodiment of the present invention, the front and rear encapsulation layers comprise a resin chosen from ethylene-vinyl acetate (EVA) resins, epoxy resins and polyolefin resins.

According to one embodiment of the present invention, the photovoltaic cells are made from crystalline silicon.

According to one aspect of the present invention, the laminate has a stiffness and an inertia such that the product of the stiffness and the inertia is less than 30,000 daN·kg·m⁻³.

The present invention also relates to a method for assembling a roof covering assembly as described above comprising the following steps:

the layers of the laminate are assembled by a lamination process,

a layer of adhesive is placed on a rear face of the laminate and/or on the support membrane,

the laminate is assembled by bonding it to the support membrane to obtain the roof covering assembly.

Other characteristics and advantages of the invention will appear more clearly on reading the following description, given by way of illustrative and non-limiting example, and on viewing the appended drawings, which include:

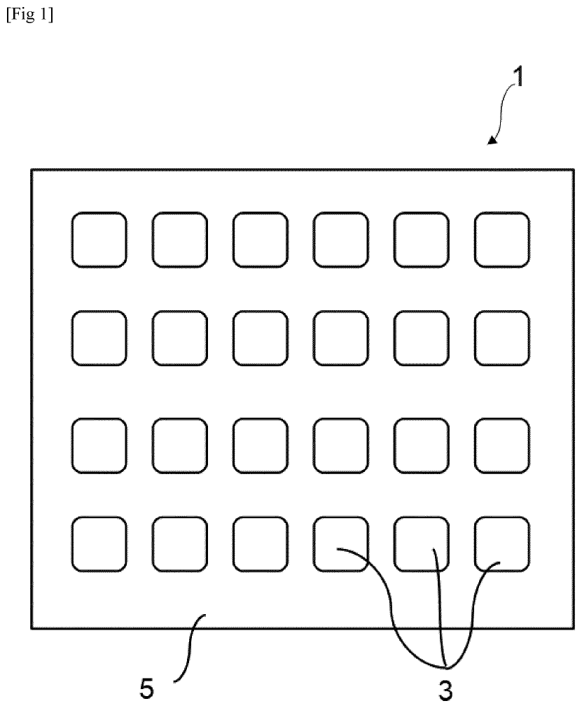

FIG. 1 shows a diagram of a photovoltaic assembly for roof covering;

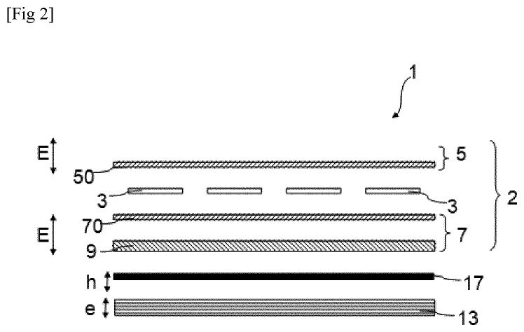

FIG. 2 shows an exploded view of the different layers of a roof covering assembly according to a first embodiment;

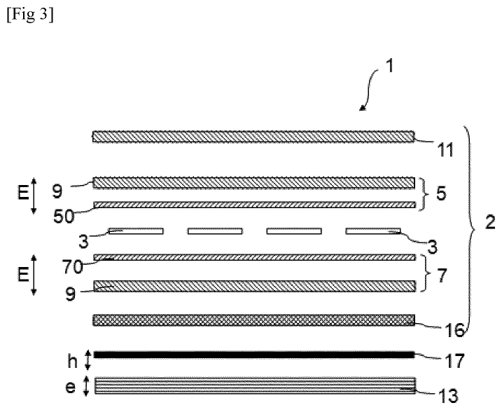

FIG. 3 shows an exploded view of the different layers of a roof covering assembly according to a second embodiment;

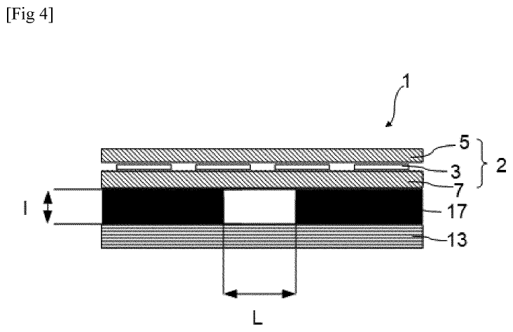

FIG. 4 shows a sectional view of a roof covering assembly;

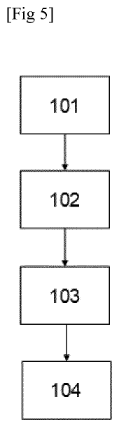

FIG. 5 shows a flowchart of the different steps of a method for assembling a roof covering assembly;

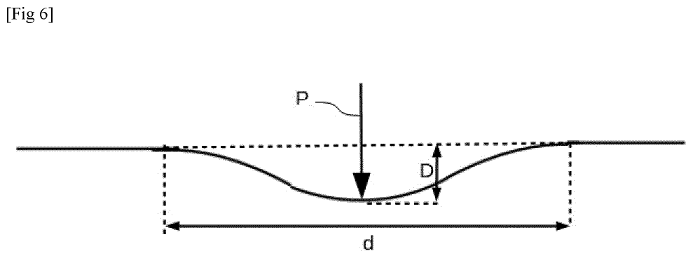

FIG. 6 represents a diagram of a local deformation of a surface under the effect of a point load.

In these figures, identical elements have the same references.

The following embodiments are examples. Although the description refers to one or more embodiments, this does not necessarily mean that each reference relates to the same embodiment or that the characteristics apply only to a single embodiment. Simple characteristics of different embodiments may also be combined or interchanged to provide other embodiments.

The term “front layer or front face” in the following description means the surface of the laminate first exposed to the sun rays in the installed state of the laminate. Similarly, the term “rear layer or rear face” in the following description means the layer (or surface) opposite the front layer (front surface), i.e., the surface which is last impacted by the sun rays during their passage through the laminate in the installed state of the laminate.

Next, the term “transparent” in the following description means a material through which light can pass with a transmittance of at least 80%, in particular at wavelengths between 315 nm and 1200 nm.

In addition, in the following description, the term “film or laminate of flexible material” means the fact that, when applying a certain radius of curvature, the film and the photovoltaic cells do not crack. In the present invention, the material should withstand without damage a radius of curvature of 1 meter.

Furthermore, with reference to FIGS. 2 and 3 representing the layers of a laminate, the different layers are spaced from each other. This representation is only made to better identify the different layers. In the delivered state of the laminate, the different layers shown are in contact with each other.

Referring to FIGS. 1, 2 and 3, they show an assembly for surface covering 1 comprising a support membrane 13 and a photovoltaic laminate 2. The surface covering 1 may correspond to a roof covering of a building or a light structure, or even a vehicle.

The support membrane 13 is, for example, a bituminous membrane having a thickness e of between 2 and 10 mm, or a membrane made of polyvinyl chloride (PVC), thermoplastic polyolefin (TPO) or ethylene-propylene-diene monomer (EPDM). In the case of a roof covering, beyond the support membrane 13, it may be possible to take into account, for stiffness purposes, an optional layer of insulation of 10 to 200 mm such as rock wool, expanded polystyrene, polyurethane, vapor barriers and support such as ribbed steel sheets, wooden decking or concrete slabs.

The laminate 2 comprises a layer of photovoltaic cells 3 connected to each other, made up of four columns of six photovoltaic cells 3, as shown in particular in FIG. 1.

The photovoltaic cells 3 forming the layer of photovoltaic cells 3 in this laminate 2 are, for example, cells based on monocrystalline or multicrystalline silicon. The use of monocrystalline silicon makes it possible to have good photovoltaic conversion yields per square meter, which limits the surface area necessary for a given energy requirement. Furthermore, such a material also has good resistance to aging, which makes it possible to increase the longevity and reliability of this laminate 2.

The laminate 2 also comprises a front encapsulation layer 5 and a rear encapsulation layer 7. The front 5 and rear 7 encapsulation layers are arranged on both sides of the layer of photovoltaic cells 3 and sandwich the layer of photovoltaic cells 3. The front 5 and rear 7 encapsulation layers are, for example, made respectively of resin layers 50 and 70. The encapsulation resin is, for example, made of epoxy or ethylene-vinyl acetate “EVA” or polyolefin resin.

The rear and/or the front encapsulation layer also comprises glass fibers 9. In the example of FIG. 2, only the rear encapsulation layer 7 comprises glass fibers 9, while in FIG. 3, the front 5 and the rear 7 encapsulation layers comprise glass fibers 9. Alternatively, only the rear encapsulation layer 7 may comprise glass fibers 9.

The front 5 and rear 7 encapsulation layers may, for example, each comprise a fabric of glass fibers 9 and an encapsulation resin 50, 70. More particularly, the encapsulation resin 50, 70 is placed between the layer of photovoltaic cells 3 and the fabric of glass fibers 9 in order to ensure the cohesion between the fabric of glass fibers 9 and the layer of photovoltaic cells 3. Alternatively, each of the two front 5 and rear 7 layers may be formed of a single layer of fiberglass fabric 9 impregnated with encapsulation resin 50, 70. The front 5 and rear 7 encapsulation layers have, for example, a thickness E of between 0.5 and 3 mm.

The laminate 2 may also include additional layers shown in FIG. 3 such as a protective layer 11, also called front layer, located on the front face of the front encapsulation layer 5.

The laminate 2 may also comprise a rear protective layer 16 disposed on the rear face of the rear encapsulation layer 7 and configured, in particular, to protect the photovoltaic cells 3 and the electrical connections between them, which are, for example, made with metal strips. The rear protective layer 16 may also include reflective properties to reflect the sun rays towards the layer of photovoltaic cells 3.

Other additional layers may also be included in the composition of the laminate 2. The laminate 2 thus forms a photovoltaic module.

The laminate 2 may be a flexible laminate. The flexibility of the laminate 1 is then obtained thanks to the constituent materials of the various layers making up this laminate 2. The use of a flexible laminate 2 for such a panel or photovoltaic module makes it possible to facilitate its transport and installation because the fragility of the latter is diminished. In addition, the weight is reduced compared to a photovoltaic module comprising a glass pane and a metal structure.

At least the front encapsulation layer 5, and any protective layer 11 are transparent to allow the sun rays to reach the layer of photovoltaic cells 3 in order to allow their conversion into electrical energy via the photovoltaic effect.

The laminate 2 is configured to be bonded to the support membrane 13 to form the assembly for surface covering 1. In addition, the assembly 1 has a stiffness and an inertia such that the product of the stiffness and the inertia is greater than 30,000 daN·kg·m⁻³. The assembly also has a stiffness greater than 10 daN/mm. At least the support membrane 13 may have a stiffness greater than 10 daN/mm. The laminate 2 has, for example, a stiffness and an inertia such that the product of the stiffness and the inertia is less than 30,000 daN·kg·m⁻³, the combination with the support membrane 13 then being necessary to obtain a stiffness and a global inertia such that the product of the stiffness by the inertia is greater than 30,000 daN·kg·m⁻³.

The stiffness (or elasticity) of the assembly 1 comprising the support membrane 13, adhesive 17 and laminate 2 is defined as the displacement D of the assembly 1 under a point load P at the point of application of the load with a reference surface corresponding to a circle having a diameter d between 10 cm and 15 cm around the point of application of the load P, as shown in FIG. 6. The stiffness is expressed in force per unit of length (N/m or, in pragmatic units, in daN/mm).

The (vertical) inertia of the assembly 1 may be reduced to the surface mass since it is the mass to be moved during an impact; it is expressed in mass per unit of horizontal surface (kg/m²). The inertia of the assembly 1 is, for example, at least 5 kg/m².

The mechanical coupling between the laminate 2 and the support membrane 13 is achieved by a layer of adhesive 17 placed between the rear face of the laminate 2 (corresponding to the rear encapsulation face 7 or, where appropriate, to the rear layer 16) and the support membrane 13. The adhesive used is, for example, butyl deposited cold in factory on the rear of the laminate 2, or bitumen deposited hot on the support membrane 13.

The thickness h of the adhesive layer 17 is, for example, between 200 μm and 1.5 mm. In addition, the adhesive is distributed so that the bonding surface represents at least 90% of an intermediate zone located between the support membrane 13 and the laminate 2, i.e., all of the portions without adhesive in the intermediate zone correspond to an area less than 10% of the total area of the faces facing the laminate 2 and the support membrane 13.

In addition, preferably, a portion of this intermediate zone without adhesive has, on the minor dimension of each of the portions, a length L less than 10 mm and a thickness I less than 1 mm, as represented by the white rectangle located in the layer of adhesive 17 in FIG. 4. By length along the minor dimension, is meant here the diameter of the largest circular surface that can be inserted in the zone without adhesive. For example, if the zone without adhesive has a rectangular shape, it will correspond to the width of the rectangle, and if the zone without adhesive has an elliptical shape, it will correspond to the small diameter of the ellipse.

In this FIG. 4, the layer of adhesive 17 is shown oversized compared to the other layers of the laminate 2 for the sake of clarity to represent a portion without adhesive.

Such an arrangement of the adhesive makes it possible to obtain a good distribution of the forces on the different layers of the assembly for surface covering 1, which thus makes it possible to limit the local deformations during an impact of hailstones.

The materials and thickness of the assembly for surface covering 1 thus formed are chosen so that the assembly for surface covering 1 has a stiffness and an inertia such that the product of the stiffness and the inertia is greater than 30,000 daN·kg·m⁻³. The assembly 1 may also have an inertia of at least 5 kg/m².

Such an assembly for surface covering 1 comprising a photovoltaic laminate 2 bonded to a support membrane 13, as described above, makes it possible to obtain an assembly for surface covering 1 whose total weight is limited while having a limited deformation under the impact of hailstones so that the photovoltaic cells 3 are not damaged by hailstones producing, for example, a kinetic energy of 2.2 joules on impact. This resistance to hail is obtained by the combination of the mechanical characteristics of the support membrane 13 and the laminate 2, as well as by the bonding quality between the laminate 2 and the support membrane 13, allowing a distribution of the forces both on the laminate 2 and on the support membrane during hail impacts, which makes it possible to limit the deformation of the laminate 2 and, therefore, of the photovoltaic cells 3.

The manufacturing steps of such an assembly for surface covering 1 will now be described from the flowchart of FIG. 5.

The first step 101 relates to the assembly of the layer of photovoltaic cells 3, the front 5 and rear 7 encapsulation layers and, optionally, the rear protective layer 13. This assembly is, for example, obtained by a conventional lamination process, i.e., by raising the temperature, under vacuum or under an inert atmosphere, for example, of a stack of the various layers forming the laminate 2, then by pressing this stack for a determined period. As indicated above, the front 5 and rear 7 encapsulation layers comprise an encapsulation resin 50, 70. At least one of the front 5 or rear 7 encapsulation layers comprises a fabric of glass fibers 9.

The second step 102, which is an optional step, relates to the deposition of a protective layer 11 on the front face of the front encapsulation layer 5. The protective layer 11 makes it possible to protect the other layers of the laminate 2.

The protective layer 11 may, for example, comprise a high transparency optical film (greater than 80 or 90%).

The third step 103 relates to the deposition of the adhesive layer 17 on the rear face of the laminate 2 and/or on the front face of the support membrane 13. The adhesive is preferably distributed uniformly over the entire surface(s) opposite the support membrane 13 and the laminate 2, i.e., at the intermediate zone located between the support membrane 13 and the laminate 2.

The thickness h of the adhesive layer 17 is, for example, between 200 μm and 1.5 mm. In addition, the adhesive is distributed so that the bonding surface represents at least 90% of an intermediate zone located between the support membrane 13 and the laminate 2.

The fourth step 104 relates to the assembling work consisting of depositing adhesive between the support membrane 13 and the laminate 2 to obtain the assembly for surface covering 1. The assembling work may be done directly on site, the support membrane 13 being previously installed, for example, on a roof, and the laminate 2 being bonded to the support membrane 13, or the assembling work may be done beforehand, the assembly 1 being then installed on the surface, for example, the roof of the building.

The embodiments described here are given by way of illustrative and non-limiting examples. Indeed, it is quite possible for a person skilled in the art to use other photovoltaic cells 3 than cells based on monocrystalline or multicrystalline silicon such as, for example, organic cells or inorganic thin layers, without departing from the scope of the present invention.

Thus, as described above, the manufacturing method involving assembling by bonding a photovoltaic laminate 2 and a support membrane 13, said assembly having a stiffness and an inertia such that the product of the stiffness and the inertia is greater than 30,000 daN·kg·m⁻³, makes it possible to obtain an assembly for surface covering 1 that can withstand bad weather and, in particular, hail. Thus, the combination of photovoltaic modules formed by a laminate, which can be flexible and light, with a support membrane 13, in particular made of bitumen, which has, for example, a stiffness greater than 10 daN/mm, makes it possible to provide an assembly for surface covering 1 easy to manufacture and install.

1. An assembly for covering a surface, comprising:
a support membrane,
a laminate comprising:
at least one layer of photovoltaic cells connected together;
a front encapsulation layer and a rear encapsulation layer sandwiching the at least one layer of photovoltaic cells;
wherein at least one of the encapsulation layers comprises glass fibers;
wherein the support membrane is bonded to the laminate; and
wherein the assembly comprising the support membrane bonded to the laminate has a rigidity and an inertia such that the product of the rigidity and the inertia is greater than 30,000 daN·kg·m⁻³.

2. The assembly according to claim 1, wherein the assembly comprising the support membrane bonded to the laminate has a rigidity greater than 10 daN/mm.

3. The assembly according to claim 1, wherein the assembly comprising the support membrane bonded to the laminate has an inertia of at least 5 kg/m².

4. The assembly according to claim 1, wherein the bonding surface represents at least 90% of an intermediate zone located between the support membrane and the laminate.

5. The assembly according to claim 4, wherein the portions of the glue-free intermediate zone has a length in the small dimension less than 10 mm and a thickness less than 1 mm.

6. The assembly according to claim 1, wherein the thickness of the adhesive layer is between 200 μm and 1.5 mm.

7. The assembly according to claim 1, wherein the support membrane is a bituminous membrane.

8. The assembly according to claim 1, wherein glass fibers are arranged in the front encapsulation layer.

9. The assembly according to claim 1, wherein the glass fibers are arranged in the back encapsulation layer.

10. The assembly according to claim 1, wherein the front and rear encapsulation layers have a thickness of between 0.5 and 3 mm.

11. The assembly according to claim 1, wherein the front and rear encapsulation layers comprise a resin chosen from “EVA” ethylene-vinyl acetate resins, epoxy resins. and polyolefin resins.

12. The assembly according to claim 1, wherein the photovoltaic cells are made from crystalline silicon.

13. The assembly according to claim 1, wherein the laminate has a rigidity and an inertia such that the product of the rigidity and the inertia is less than 30,000 daN·kg·m⁻³.

14. A method of assembling a surface covering assembly, according to claim 1, comprising the following steps:
assembling the layers of the laminate by a lamination process;
placing a layer of adhesive on a rear face of the laminate and/or on the support membrane; and
assembling the laminate by gluing on the support membrane to obtain the assembly for surface coverage.

15. The assembly of claim 1, wherein the surface is a roof.
